(19) United States
(12) Patent Application Publication
(10) Pub. No.: US 2026/0201535 A1
(43) Pub. Date: Jul. 16, 2026

(54) Polarizer Stencil Mask

(71) Applicant: University of Copenhagen, Copenhagen K (DK)

(72) Inventors: Michaela Eichinger, Copenhagen Ø (DK); Thomas Kanne Nordqvist, Copenhagen Ø (DK); Tobias Skov Særkjær, Copenhagen Ø (DK); Morten Kjærgaard, Copenhagen Ø (DK); Peter Krogstrup Jeppesen, Copenhagen Ø (DK)

(21) Appl. No.: 19/138,248

(22) PCT Filed: Jun. 19, 2023
(86) PCT No.: PCT/EP2023/066474

§ 371 Date: Jun. 12, 2025

(30) Foreign Application Priority Data
Dec. 15, 2022 (EP) 22213759.8

(51) Int. Cl. C23C 14/04; C23C 14/24

(52) U.S. Cl. CPC C23C 14/042; C23C 14/24

(57) ABSTRACT

The present disclosure relates to a stencil mask for defining a plurality of patterns on a substrate during evaporation of material from an evaporation source, the stencil mask comprising a membrane having a top surface and bottom surface and a thickness therebetween of at least 200 nm defining the thickness of the membrane, and a at least one set of parallel slits extending through the thickness of the membrane, wherein the slits are defined such that the material coming from an evaporation source is blocked by the mask or deposited onto the substrate depending on the alignment of said source with the stencil mask.

The present disclosure relates to a stencil mask and a method for defining patterns on substrates, suitable for fabrication of nanoscale devices, semiconductor devices, biological applications, flexible electronics or photonics.

### BACKGROUND

Developments in nanofabrication tools have contributed to the major leaps in the semiconductor device manufacturing. Solid state quantum computation heavily relies in the reproducible fabrication of devices and its development is also tightly correlated to the improvement of the nanofabrication techniques being used in the process. Cleaner, faster and more precise nanofabrication processes have been demonstrated to improve the performance of the resulting devices.

The fabrication of quantum bits “qubits”, require the use of extremely controlled environments in terms of cleanliness and temperature. Ultra-high vacuum (UHV) systems with a high control of temperature and pressures are used for the fabrication of qubits due to the high vacuum levels achieved and the control of temperature along a range of hundreds of ° C.

Performing as many qubit fabrication steps as possible inside UHV systems have been demonstrated to improve the qubit performance and reproducibility during quantum transport experiments. Stencil mask fabrication of qubit devices inside UHV systems is a technique that has gained attention during the recent years due to their ability of imprint devices on substrates inside UHV. The use of stencil masks overrides the necessity of extracting substrates from the UHV material growth systems and performing depositions in ex-situ systems, thus maintaining the pristine conditions of the fabricated samples and devices.

Previously disclosed stencil lithography masks typically comprise a single pattern that can be imprinted onto a substrate. Said pattern allows the selective deposition of a first material, whilst if a second material needs to be deposited in a different pattern onto the substrate, a second stencil lithography needs to be inserted into the UHV system. In general, the introduction of additional materials into UHV systems imply a degradation of the pristine conditions inside it, reducing the performance of the fabricated quantum devices.

US 2022/035250 discloses a mask sheet provided with a plurality of open areas defined therein in a plan view and a mask frame which supports the mask sheet and configured to be in contact with a target substrate, and a second inclined surface inclined downward with respect to the first direction. The stencil mask comprises openings or slits of a width of 3 μm.

JP 2020 125507 discloses a vapor deposition mask comprising a thin film-shaped mask body provided with a plurality of openings, a holding frame provided around the mask body, and a connection member for connecting the mask body to the holding frame. The mask is fabricated via conventional wet etch fabrication methods.

US 2003/150384 discloses aperture masks and deposition techniques employing laser ablation and optical lithography means to define apertures on a stencil masks.

### SUMMARY

Considering the prior art described above, it is a purpose of the present disclosure to provide a stencil mask for defining at least one pattern on a substrate during evaporation of material from an evaporation source, the stencil mask comprising, a membrane having a top surface and bottom surface and a thickness therebetween defining the thickness of the membrane and at least one set of parallel slits (possibly even a plurality of sets of parallel slits) extending through the thickness of the membrane. The longitudinal axis of the slits (extending through the membrane from the bottom surface to the top surface) in a set of parallel slits typically define an in-plane angle within the membrane of the stencil mask. The thickness of the membrane is preferably at least 100 nm, more preferably at least 200 nm, most preferably at least 1 μm or even at least 5 μm.

The slits are preferably defined such that the material coming from an evaporation source is blocked by the mask or deposited onto the substrate depending on the alignment between said source and the in-plane angle of the at least one set of slits on the stencil mask. The position of the source with respect to the stencil mask can be defined in terms of azimuth angle and elevation angle.

Thus, with the disclosed stencil mask it is possible to block a desired material being evaporated onto a substrate by orienting the source to a selected orientation with respect to the stencil mask. The effect of selectively blocking a deposition is due to the different orientation of the slits with respect to the source of evaporation. Due to the relatively high thickness of the polarizer stencil mask of preferably at least >1 μm, a different orientation of the slits with respect to the evaporation source causes the evaporated material to be blocked by the walls of the slits, hence polarizing the deposition as a function of the relative orientation between mask and source. This allows to deposit more than one different pattern by using the same mask, only by modifying the azimuth and elevation angle of the evaporating source with respect to the mask. The concept of selectively blocking a deposition with a stencil mask due to the spatial orientation is defined as polarization of the evaporation and the mask is defined as polarizing stencil mask.

Preferably, a polarizer stencil mask comprises more than one pattern. Each pattern is defined such that only a precise combination azimuth and elevation angles of the mask with respect to the evaporation source allows the transmission of evaporated material onto the surface. By precise combination of azimuth and elevation angles it is understood an alignment of the slits on the mask with respect to the evaporation source such that the angular error on the positioning of the mask with respect to the evaporation source is smaller than the range of angles on the positioning of the mask with respect to the evaporation source that allows the evaporated material to pass through the mask. Typically, the range of angles of the position of the mask with respect with the evaporation source that allows the evaporated material to pass through the mask is <5° in azimuth and/or elevation, being able to be improved by optimizing the nanofabrication techniques used during the fabrication of the mask.

Advantageously, multiple patterns of different evaporation materials might be deposited onto a substrate using a single polarizer stencil mask and without the necessity of introducing additional masks into the UHV system for each different pattern.

The present disclosure further relates to a method a method for defining a plurality of patterns on a substrate by evaporation from one or more evaporation sources using different evaporation materials. The method comprises the steps of providing a substrate and a stencil mask comprising a plurality of sets of parallel slits, rotating the substrate to a predefined azimuth and elevation angles defined between a plane of the surface of the mask and the spatial location of the evaporating source with respect to the mask, evaporating one or more materials over the mask, and optionally repeating the previous steps until all the intended materials are deposited.

One of the key advantages of the polarizer stencil mask is its versatility. The polarizer stencil mask enables the realization of virtually any design into a single corresponding inorganic stencil mask. This represents a significant difference from prior art stencil and organic lithography methods, which can often impose limitations on the design and result in parasitic polarizer structures. Any device design may in principle be engineered into a corresponding inorganic polarizer stencil mask.

Having precise control of the mask-substrate distance is crucial for successfully growing high quality devices. In addition, the growth process of a semiconductor on a desired substrate is possible via the use of the herein disclosed polarizer stencil, in particular, a monolithical integration of III-V semiconductors on silicon is a suitable application. Said integration is also an actively pursued topic for photonic and traditional integrated circuits.

The stencil mask of presently disclosed method may be the presently disclosed stencil mask.

### DESCRIPTION OF DRAWINGS

The present disclosure will in the following be described in greater detail with reference to the accompanying drawings:

FIG. 1 shows a schematic view of one embodiment of the presently disclosed polarizer stencil mask.

FIG. 2 shows a simulated deposition using the stencil mask model from FIG. 1, at a mask distance from the substrate of 1 nm.

FIG. 3A, 3B shows a simulated deposition using the stencil mask model from FIG. 1, at a mask distance from the substrate of 5 μm.

FIG. 4A, 4B shows a simulated deposition using the stencil mask model from FIG. 1, with a mask width of 500 nm.

FIG. 5A, 5B shows a simulated deposition using the stencil mask model from FIG. 1, with a mask width of 100 nm.

FIG. 6A, 6B shows a simulated deposition using the stencil mask model from FIG. 1, with a bridge width of 300 nm.

FIG. 7A, 7B shows a simulated deposition using the stencil mask model from FIG. 1, with a bridge width of 50 nm.

FIG. 8 shows a schematic view of one embodiment of the presently disclosed polarizer stencil mask with illustration of the deposition angles, azimuth φ and elevation θ.

FIG. 9A, 9B shows a simulated deposition using the stencil mask model from FIG. 8, with an azimuth angle of 180°.

FIG. 10A, 10B shows a simulated deposition using the stencil mask model from FIG. 8, with an azimuth angle of 160°.

FIG. 11A, 11B shows a microscope images of an example of a polarizer stencil mask.

FIG. 12 shows a simulated deposition on the left and a microscope image on the right of an example of a polarizer stencil mask and a deposition.

FIG. 13 a device prototype fabricated with one embodiment of the presently disclosed polarizer stencil mask.

FIG. 14 a schematic example of the use of the polarizer stencil mask for the growth of a semiconductor device and metallic deposition afterwards.

### DETAILED DESCRIPTION

In the preferred embodiment the presently disclosed polarizer stencil mask comprises arrays of nanofabricated features. Said features typically comprise a set of slits and bridges. A slit is an opening throughout the thickness of the stencil mask, wherein a material evaporated from one side of the of the stencil mask can traverse through it towards the other side of the stencil mask. A set or array of slits is a plurality of slits arranged in an orientation predominantly parallel to each other, defined by a parameter b determining the distance between each slit comprising the array. The plurality of slits are predominantly separated by the inter-slit distance b. The material comprised between two adjacent slits is defined as a bridge. Each set of parallel slits is defined to imprint a distinct pattern on a substrate located at some distance from the opposite side of the mask from a material evaporation source during a material evaporation process.

By material evaporation it is meant a nanofabrication process comprising a deposition of materials, typically of high purity originating in an evaporation cell, onto a substrate. The evaporation cell might be for example an effusion cell located in an UHV molecular beam epitaxy growth system, a sputtering target from a sputtering process system or in general any source or cell that evaporates a source material onto a target.

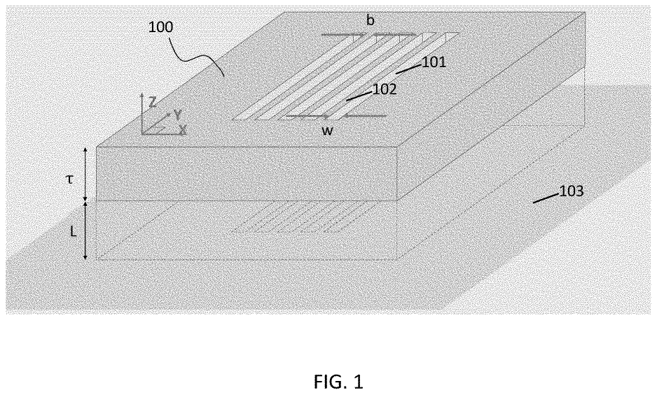

FIG. 1 shows a schematic view of an embodiment of a polarizer stencil mask 100 showing the typical components. The polarizer mask is comprised of slits 101 of width w and bridges 102 of width b located between the slits, wherein the thickness of the mask is t and the distance between the mask and the substrate 103 is L. The bridges might be comprised of the same material than the rest of the polarizer stencil mask. The slits might be defined on the mask by nanofabrication processes such as for example wet etch or dry etch techniques.

In a preferred embodiment, the thickness t of the mask is at least 200 nm, or 500 nm, preferably at least 1 μm, more preferably at least 3, most preferably at least 5 μm. Stencil masks of a thickness of at least 1 μm are considered high thickness stencil mask in the nanofabrication field. One example of a nanofabrication process for providing a large thickness stencil mask of at least 1 μm is for example disclosed in pending European patent application no. 22180214.3 by the same applicant, which is hereby incorporated by reference in its entirety.

Due to the relatively small thickness of the membrane t, the stencil mask b can also be defined as a membrane in the nanotechnology field. Previously disclosed stencil mask membranes comprise a material layer wherein a pattern is imprinted on it, wherein the thickness of the layer is typically ~50 nm. The thickness of the herein disclosed membrane is typically at least 5 μm, where nanofabrication layers are still defined as membranes. Due to the improvement in recent years of nanofabrication techniques, stencil patterns on membranes of 5 μm in thickness are possible to be fabricated, while still conserving the slits of the pattern a high aspect ratio of the walls along the whole thickness of the membrane. The width w of parallel slits might be at least 10 nm, preferably 50 nm and more preferably at least 200 nm. The smallest widths b are limited by the nanofabrication technique used to define them on the membrane and the biggest widths b being arbitrarily big. The separation between parallel slits, defined by the bridge width b, might be at least 10 nm and preferably at least 50 nm.

Typically, the length of the sets of slits of the polarizer shadow mask might be at least 50 nm, preferably 200 nm, more preferably 1 μm or even more preferably longer than 100 μm. However, the parameters b, w and the length of the slits may be bigger than the dimensions stated in this preferred embodiment, depending on the particular deposition to be performed, the material being deposited or the characteristics of the imprinted pattern. The limitations on the dimensions of the parameters b, w and the length of the slits is determined by the limitations imposed by the nanofabrication process used, typically determined by the resolution of the lithography nanofabrication setups.

Similarly to the coordinate system used in astronomy, the in-plane angle orientation of the slits fabricated on the stencil membrane is defined with respect to an evaporation source.

The angle azimuth φ is defined for every array of slits as an angle around an axis perpendicular to the substrate of the stencil mask. The azimuth angle is hence understood as an in-plan rotation of the surface of the substrate, around any axis perpendicular to its surface. It is defined as φ=0° for arrays of slits having a major axis defined by the longest side of a slit pointing towards the direction of the projection point of the evaporation source location on the stencil mask.

Similarly, an elevation angle θ is defined for every array of slits as the smallest angle between the substrate and the evaporation source. Alternatively, the elevation angle θ may be defined for every array of slits as the angle between two lines, said lines are a line connecting the center of the arrays and a projection point of the evaporation source onto the substrate, and a line connecting the center of the sets of slits and the evaporation source. Assuming this definition, the range of the elevation angle is θ∈(0,90]°. It is defined as θ=90° for a surface of the stencil mask being perpendicular to the evaporation source. Hence, the location of the evaporation source with respect to the set of slits is uniquely defined by an azimuth φ and an elevation θ angles.

In a preferred embodiment, a stencil mask of thickness τ comprising slits of width w only allows deposition of material from an evaporation source to pass through the slits to a deposition substrate located beneath the stencil mask in a range of azimuth angles φ∈[0, φ_{threshold}]. For a deposition source located at an elevation angle θ, the φ_{threshold} is defined by the geometry of the stencil mask by

$${ϕ}_{threshold} = arctan ( {[ {( \frac{τ}{w} )}^{2} {tan}^{2} ( θ ) - 1 ]}^{- 1 / 2} ) .$$

In another embodiment, a substrate comprises a plurality of sets of slits. Each set of parallel slits comprises at least one slit, wherein each set might be defined in a different azimuth angle on the substrate. Each set of slits might comprise a different azimuth angle between each other of ≥1°.

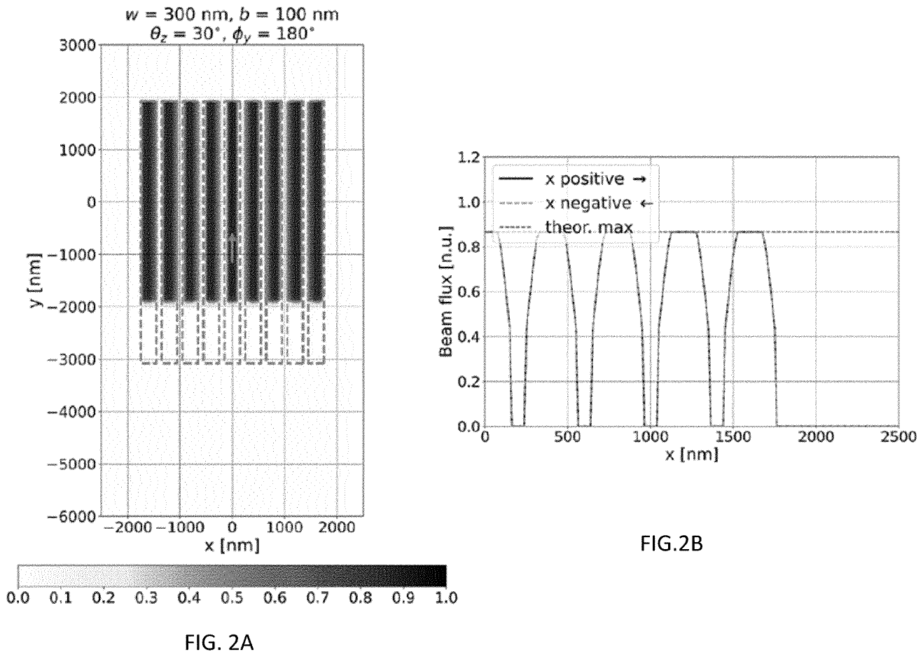

FIG. 2 shows a simulation of a material evaporated over a polarizer stencil mask to define a pattern onto a substrate. In the example of FIG. 2A, an array of slits is defined with the parameters w=300 nm, b=100 nm and the deposition is performed at the angles φ=180° and θ=30°. The separation between the polarizer stencil mask and the substrate is set at 1 nm. The color scale denotes the amount of material deposited in the underneath substrate, “1” being an arbitrary amount equal to the complete amount of material being deposited and “0” absence of material. FIG. 2B is a perpendicular line scan of the height of the deposition, across the deposition. It is observed that at this configuration, the maximum amount of deposition is above 0.8, being the theoretical maximum. It is observed in the line scan that between the bridges there is no deposition of material, due to the direct shadowing of the bridges.

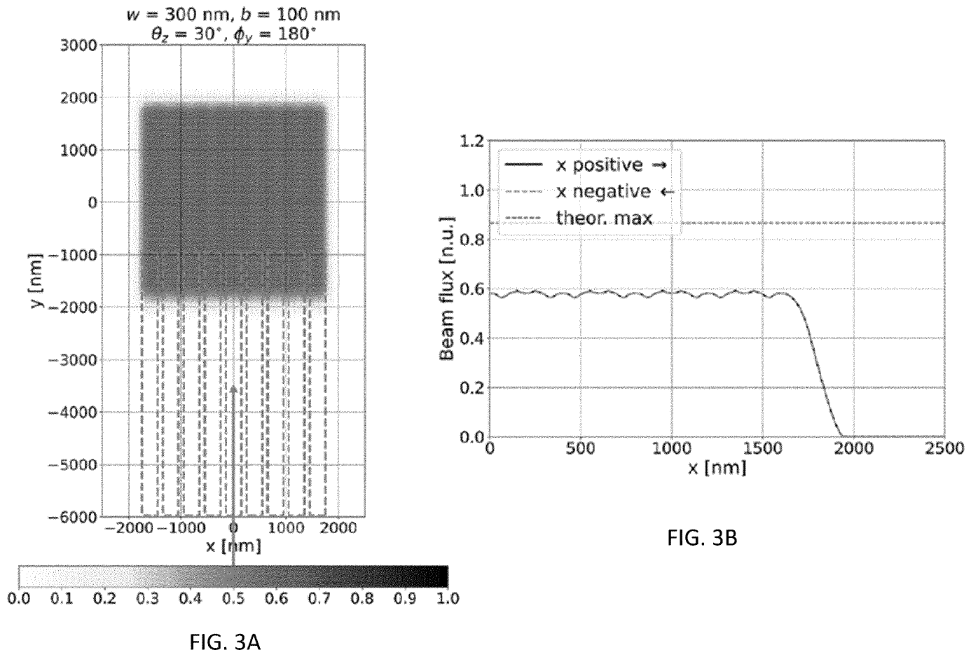

FIG. 3 shows a simulation experiment identical to FIG. 2, but increasing the distance between the substrate and the polarizer stencil mask from L=1 nm to L=5 μm. FIG. 3A shows a homogenization of the deposited material on the substrate that passed across the stencil mask. FIG. 3B shows a line scan of the height of the deposited material. In contrast to FIG. 2B, the overall height of the deposition is almost constant along its width, with a deposition rate of almost 0.6. Hence, the impact of the bridges on the deposition is minimized by increasing the parameter L.

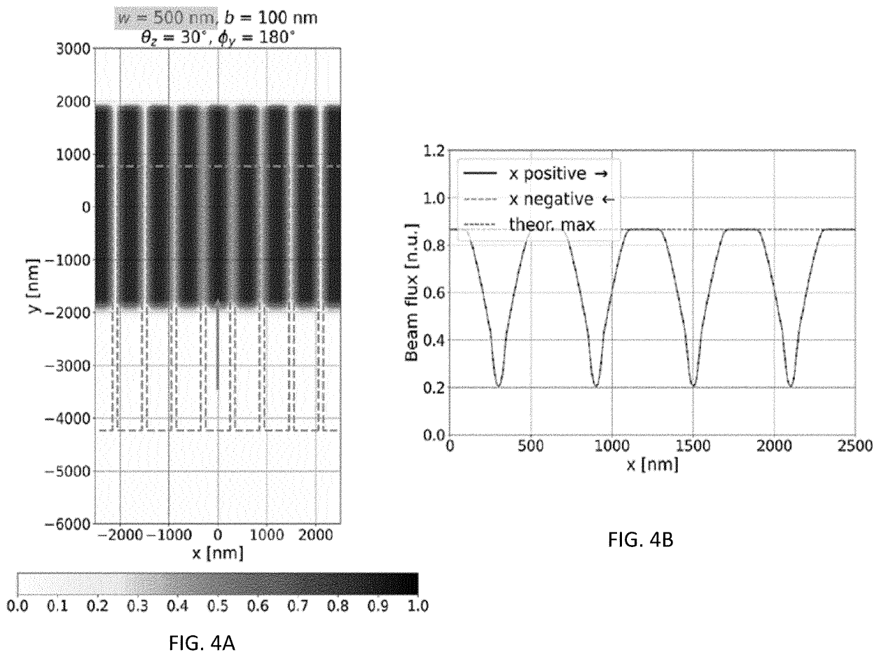

FIG. 4 shows a simulation of a material evaporated over a polarizer stencil mask to define a patter onto a substrate. In the example of FIG. 4A, an array of slits is defined with the parameters w=500 nm, b=100 nm and the deposition is performed at the angles φ=180° and θ=30°. The separation between the polarizer stencil mask and the substrate and the thickness of the polarizer stencil mask is kept constant. FIG. 4A shows a deposition wherein the shadowing effect of the bridges affects the homogeneity of the height of the deposition. FIG. 4B shows a line scan of the height of the deposition, wherein the maximum height is above 0.8, similarly to the result from FIG. 2A and the minimum height is 0.2.

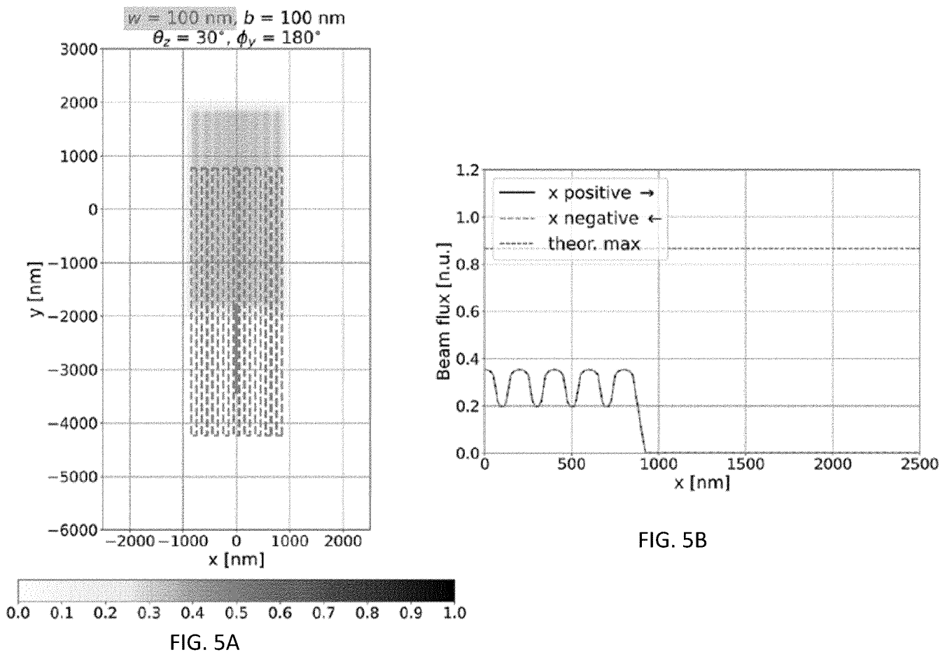

FIG. 5 shows a simulation experiment identical to FIG. 4, but decreasing the width w of the slits to w=100 nm and keeping the rest of the parameters constant with FIG. 4. FIG. 5A shows a more constant deposition in height, in comparison with FIG. 4A. FIG. 5B shows a line scan of the height of the deposition, where in the height difference between maximum and minimum is smaller than the simulation from FIG. 4B with wider slits. The overall height of the deposition is decreased to a mean value of around 0.3. Hence, the result of reducing the slit width w is to reduce the overall deposition height of the maximum and to minimize the height differences between the maximum and minimum heights of the depositions.

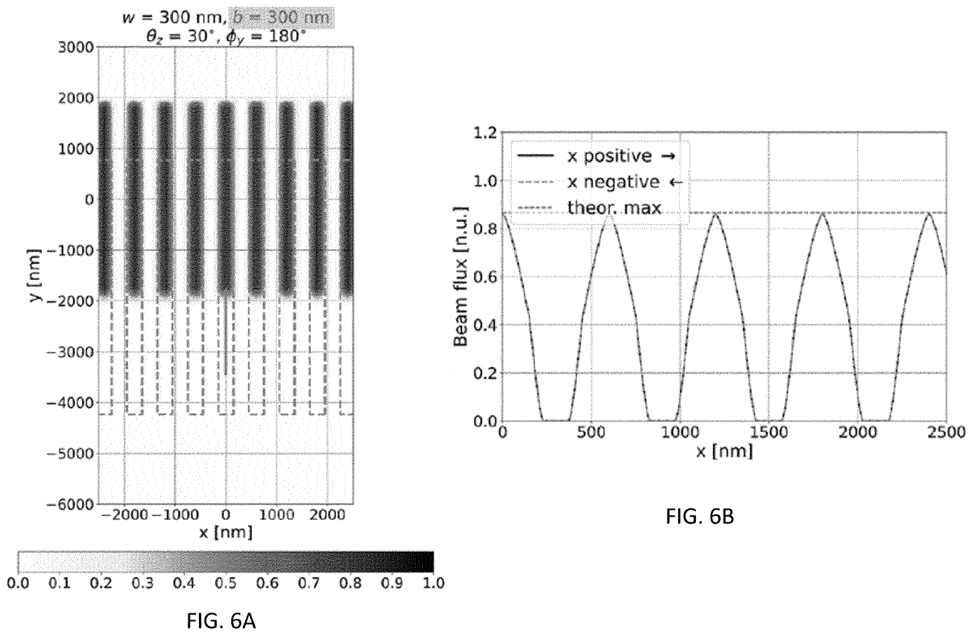

FIG. 6 shows a simulation of a material evaporated over a polarizer stencil mask to define a pattern onto a substrate. In the example of FIG. 6A, an array of slits is defined with the parameters w=300 nm, b=300 nm and the deposition is performed at the angles φ=180° and θ=30°. The separation between the polarizer stencil mask and the substrate and the thickness of the polarizer stencil mask is kept constant. FIG. 6A shows a deposition wherein the shadowing effect of the bridges affects the homogeneity of the height of the deposition. FIG. 6B shows a line scan of the height of the deposition, wherein the maximum height is above 0.8, similarly to the result from FIG. 5A and the minimum height is 0.

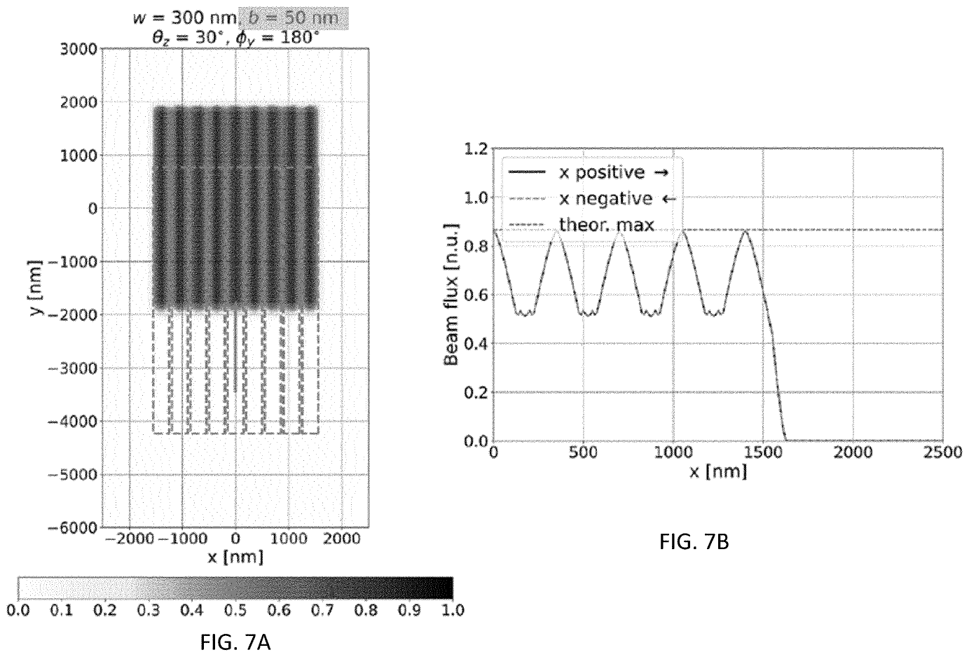

FIG. 7 shows a simulation experiment identical to FIG. 6, but decreasing the width b of the bridge to b=50 nm and keeping the rest of the parameters constant with FIG. 6. FIG. 7A shows a more constant deposition in height, in comparison with FIG. 6A. FIG. 7B shows a line scan of the height of the deposition, where in the height difference between maximum and minimum is smaller than the simulation from FIG. 7B with wider bridges. The overall height is kept constant whereas the minimum is increased to 0.5. Hence, the result of reducing the bridge width b is to increase the overall deposition height of the minimum and to minimize the height differences between the maximum and minimum heights of the depositions.

In another embodiment, the side walls of the sets of parallel slits might be fabricated perpendicular to the plane of the surface of the membrane. Similarly, the side walls of the sets of parallel slits might be fabricated at an angle <90° with respect to the plane of the surface of the membrane. The side walls of each of the parallel slits might define as well a different angle with respect to the plane of the surface of the membrane. Said angle might be monotonically increasing, suitable to allow the deposition of evaporated materials at a single height of the source of material from the polarizer stencil mask.

Preferably, the polarizer stencil mask is comprised of a selectively etching material, preferably selected from the group of semiconductors such as Si, SiN, SiC, ceramics, metals or polymers. In particular, it might be fabricated by a material resistant to chemical agents capable of dissolving the materials being evaporated in the evaporation processes. In addition, the mask is also preferably comprised of a material mechanically and chemically stable at temperatures of hundreds of ° C., preferably 500° C., preferably selected from the group of semiconductors such as Si, SiN, SiC or ceramics or polymers.

In another embodiment, two sets of parallel slits are defined in interleaving superposition defining a mesh of slits on the mask. For example, the two sets of parallel slits defining the mesh might be defined forming an angle between each other, preferably orthogonal.

In yet another embodiment, the slits defined on the polarizer stencil mask comprise a set of slits having a polyhedral closed shape, such as a square, a rectangle or a circle.

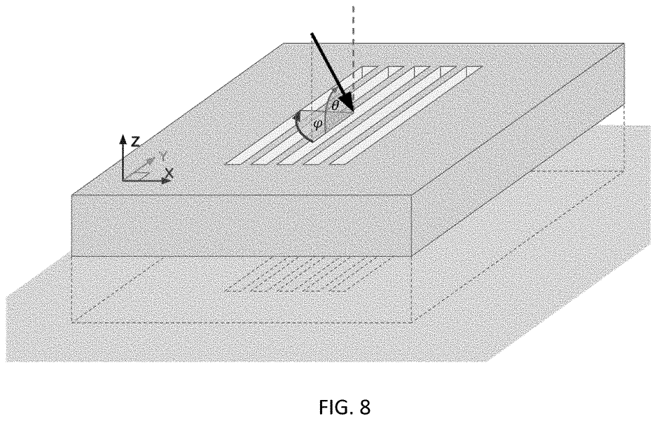

FIG. 8 shows a schematic view of the same polarizer stencil mask as in FIG. 1, wherein the angles defining the incoming direction of the evaporated material from the material source are defined by an azimuth angle φ and an elevation angle θ.

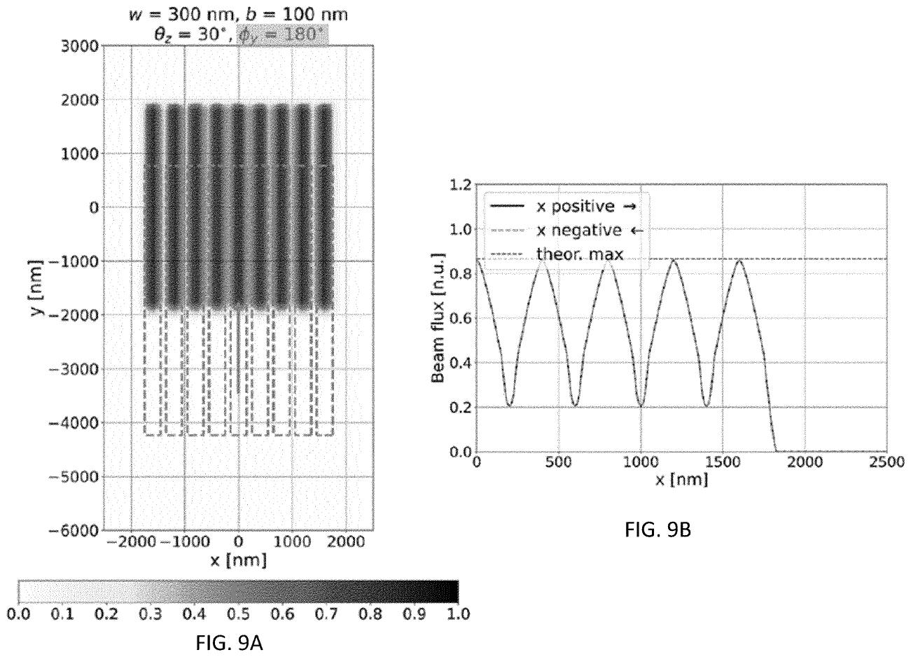

FIG. 9 shows a simulation of a material evaporated over a polarizer stencil mask to define a patter onto a substrate. In the example of FIG. 9A, an array of slits is defined with the parameters w=300 nm, b=100 nm and the deposition is performed at the angles φ=180° and θ=30°. The separation between the polarizer stencil mask and the substrate and the thickness of the polarizer stencil mask is kept constant. FIG. 9A shows a deposition wherein the shadowing effect of the bridges affects the homogeneity of the height of the deposition. FIG. 9B shows a line scan of the height of the deposition, wherein the maximum height is above 0.8, similarly to the result from FIG. 4B and the minimum height is 0.2.

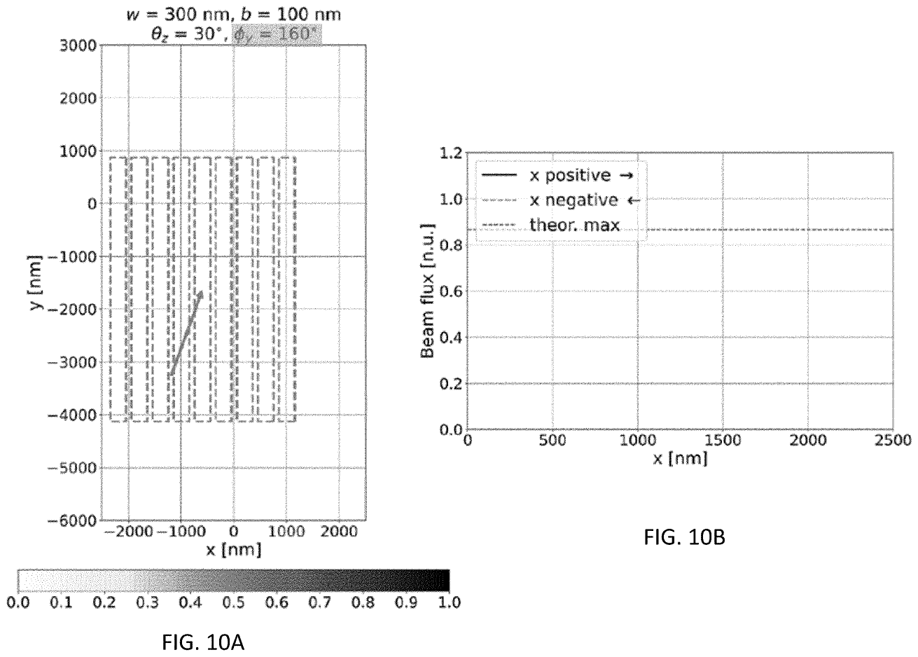

FIG. 10 shows a simulation experiment identical to FIG. 9, but decreasing the azimuth angle to φ=160° keeping the rest of the parameters constant with FIG. 9. FIG. 10A shows an absence of deposition on the substrate. FIG. 10B shows a line scan of the height of the deposition, wherein no deposition at all is seen on the substrate. This is caused by the polarizer mask stopping any of the material being evaporated on it due to the azimuth and elevation angles of the evaporation source with respect to slits orientation. The polarizer mask is effectively filtering out the deposition as it is not within the set of coordinates that allows the evaporated material to pass through it. Hence, it is possible to allow or to block a deposition based on the relative orientation of the polarizer stencil mask with respect to the evaporation source.

Similarly, it is possible to define a plurality of patterns on a substrate by evaporation from one or more evaporation sources using different evaporation materials, comprising the steps of providing a substrate and a stencil mask comprising a plurality of sets of parallel slits, rotate the substrate to a predefined azimuth and elevation angles defined between a plane of the surface of the mask and the spatial location of the evaporating source with respect to the mask, evaporating one or more materials over the mask, and optionally repeating the previous steps until all the intended materials are deposited.

The control of selecting which of the evaporated materials are deposited on the substrate based on the azimuth and elevation angles allows to deposit more than one evaporated material defining the same pattern on the substrate. It also allows more than one evaporated material to be deposited at the different azimuth and elevation angle, defining different patterns on the substrate.

In another embodiment, the polarizer stencil mask can be used to generate as thin line depositions as arbitrarily desired. This deposition is achieved by orienting the evaporation source in a particular azimuth and elevation angles with respect to the polarizer stencil mask which are close to the angles that completely block the evaporated material to be deposited.

Different evaporation of materials might be deposited in different or identical patterns simultaneously, depending in the relative orientation of each evaporation source with respect to the polarizer stencil mask. In addition, evaporation of materials in different or identical patterns might be performed in a specific temporal order.

The substrate wherein the deposition is deposited onto is comprised of a solid mostly flat surface material, such as for example crystalline semiconductor GaAs, GaSb, InP, InAs, InSb, Si, SiC, SiN, semiconductor alloys or sapphire. Other substrates might be used according to the type of pattern that is imprinted onto.

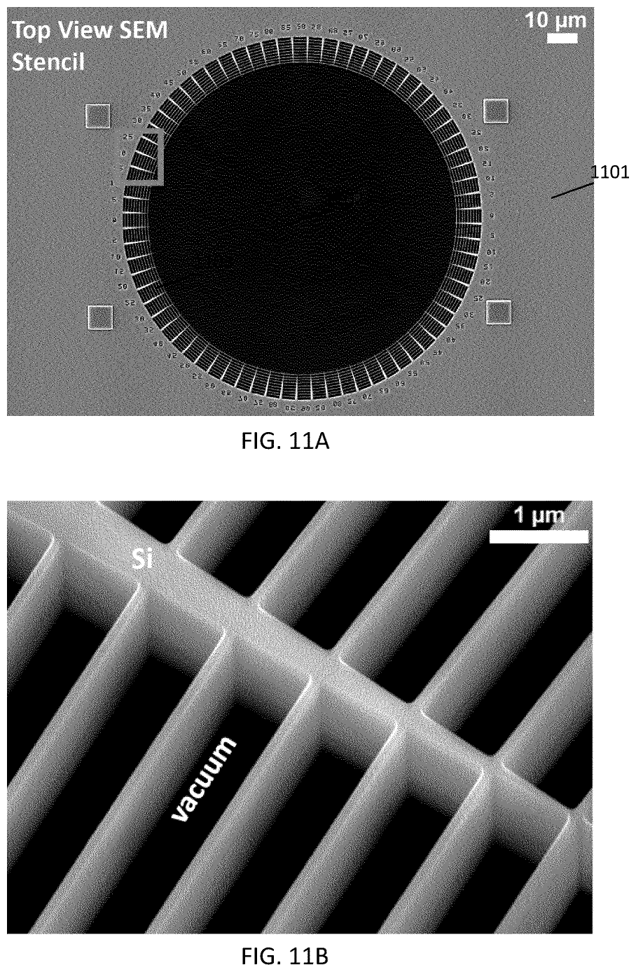

FIG. 11 shows an electron microscope image of a fabricated polarizer stencil mask. The mask is comprised of Si and it is fabricated via the clear-oxide-remove-etch nanofabrication process. FIG. 11A shows an overview of the membrane 1101 wherein the polarizer mask is fabricated on. The black parts 1102 located in the center of the membrane are vacuum or places where the Si has been completely etched away. The structures between the membrane 1101 and the central part 1102 comprise the polarizer stencil mask 1103. FIG. 11B is a high magnification polarizer stencil mask 1103 wherein a set of slits is defined and separated by bridges of a smaller width. In this particular realization of a polarizer stencil mask, it is defined a set of slits located at all possible azimuth angles in steps of 5°.

The main challenge in making the before mentioned proposals of polarizer stencil masks is controlling deformations in the silicon membranes, which may arise from the etching of larger apertures or from metal accumulation on the stencil's backside during the evaporation process. Additionally, prior art unprocessed membranes even deflect by a few hundred nanometers. This is caused by intrinsic strain originating from the surrounding silicon frame. Nonetheless, novel strain compensation techniques for silicon/silicon-nitride based membranes have been proposed and experimentally demonstrated addressing the individual deformation sources. These include deploying strain compensation films, the utilization of compliant membranes that are mechanically decoupled from a rigid silicon frame, or adding stabilizing corrugation features. Stencil membranes were designed with micro hotplates that bend them towards the substrate by thermal actuation. Besides, the ability to use finite element methods to simulate stress mechanisms might be useful tool for creating tailored solutions for polarized silicon membrane stencils.

The evaporated materials might be comprised of materials compatible with ultra high vacuum evaporation process, such as metals like Al, Au, Ag, Pb, or semiconductor growth precursors. As well, sputtering-compatible materials might be used during the selective deposition of materials using the polarizer stencil mask. Semiconductor growth precursor may be type III-V semiconductor precursors, type II-VI semiconductor precursors, type IV semiconductor precursors, any alloys comprised of said precursors or other elements used in the semiconductor and quantum electronic industries capable of being vaporized. Different evaporation sources for semiconductor growth may operate at different flux ratios, different temperatures or different deposition angles. Subsequent depositions of metals or semiconductors may be performed in a series of depositions to create multi-layer stacks of materials.

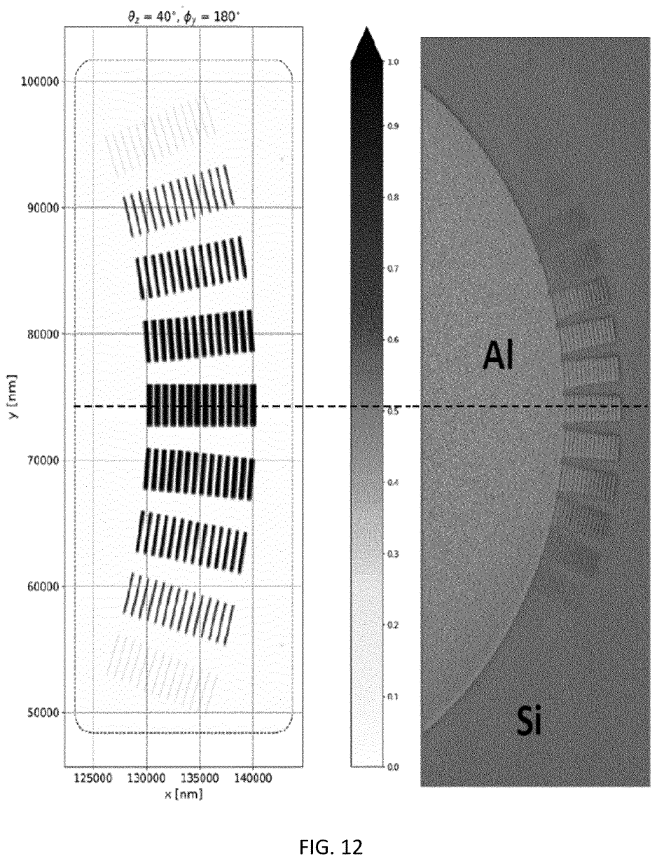

FIG. 12 shows on the left a simulation experiment of a deposition based on the polarizer stencil mask shown in FIG. 11. The coordinates of the evaporation source with respect to the mask are azimuth φ=180° and elevation θ=50°. It is apparent that only the material being evaporated at a precise orientation are not blocked by the polarizer stencil mask. On the right part of the figure, a scanning electron microscope image shows an experimental evaporation of Al using the mask modelled in the left part of FIG. 12. Only the Al arriving to the slits oriented at a precise orientation reached the underneath Si substrate, being the rest of evaporation blocked due precise orientation of the sets of the slits in comparison with the orientation of the evaporation source. In this case, the evaporation have been polarized due to the geometry of the polarizer stencil mask.

The size of the imprinted pattern might not be limited by the polarizing property of the disclosed stencil mask. Hence, an imprinted deposition might have a surface area of >0.01 μm², preferably >1 μm², more preferably >10 μm², even more preferably >100 μm².

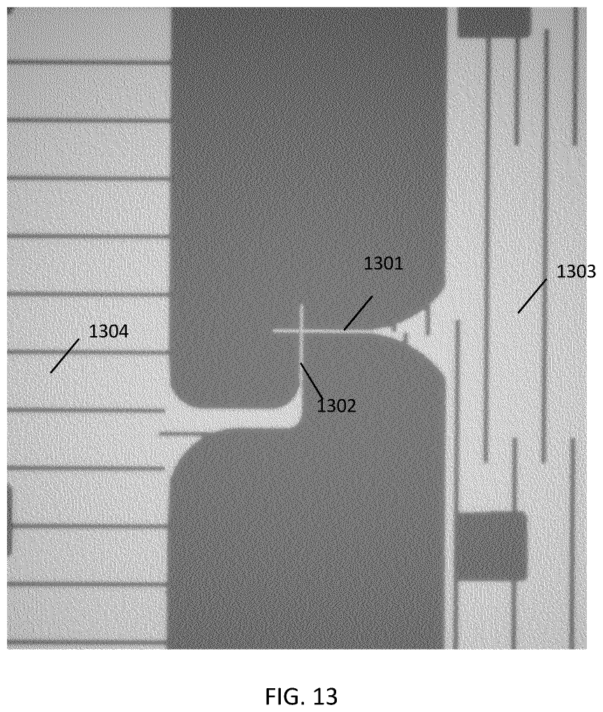

FIG. 13 shows a particular example of a quantum device fabricated with the presently disclosed polarizer stencil mask. The device comprises first and second superconducting Al islands, wherein a region 1301 from the first island is defined on top of a region 1302 of the second island. Both islands are separated by a layer of an insulating material of a thickness of few nm, forming a Josephson junction quantum device. In this particular example, a first Al deposition is performed defining the Al island comprising the first region 1301, an oxidation step is performed on substrate to oxidize the first ~5 nm of the first Al island and a second Al deposition. Each Al deposition is performed such that the relative orientation of the mask and the evaporation source only allows the evaporated material to define one Al island. FIG. 13 demonstrates the versatility of the polarizer shadow mask and the compatibility with other nanofabrication processes in between a series of material evaporation steps.

Each individual slit comprising a set of slits might have different length. For example, in FIG. 13 one set of slits defined the Al island 1303. Among the slits comprising the set, one of the slits was fabricated longer than the rest, generating the structure 1301 during the evaporation. A different set of slits generated the second Al island 1304, having the set a different azimuth angle than the set that generated the island 1303. The number of slits comprising a set of slits is defined depending on the area of the pattern that the set will imprint onto the substrate. An estimation of the number N of slits needed to define a pattern might be calculated as the surface/length L of the pattern to be printed divided by the sum of the width of the slit w and the width of the bridges b:

$$N ∼ \frac{L}{w + b} .$$

Hence, the number of slits in a set of slits can vary from a few slits to tens of slits, or hundreds of slits or even thousands of slits.

The presently disclosed polarizer stencil mask may be used in other technical fields apart from semiconductor nanofabrication, where stencil lithography is extensively used, such as for example biology, flexile electronics or photonics applications.

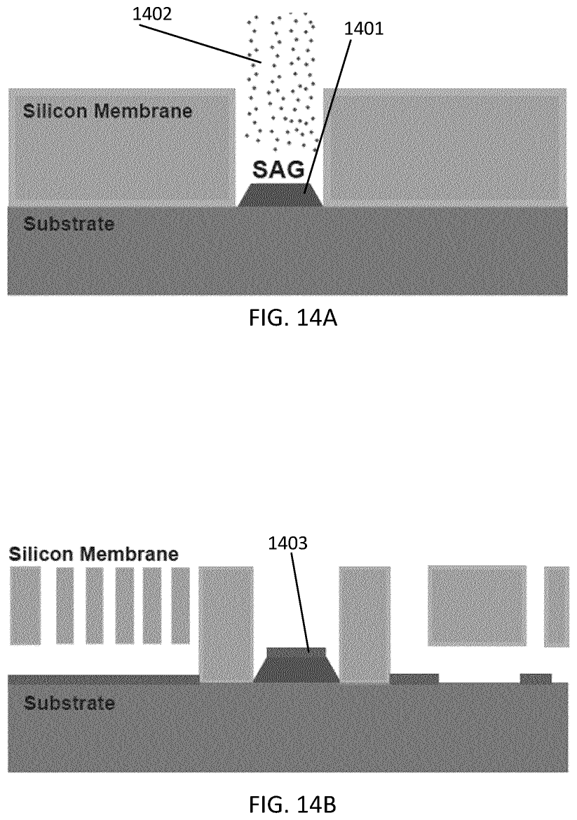

The herein disclosed polarizer stencil mask may be used to selectively grow semiconductor structures. Similarly to the shadowing effect of an evaporation source at given φ and θ conditions, the polarizer stencil mask may define a predefined pattern on the underneath substrate to selectively guide the growth of semiconductor structures. Semiconductor growth precursors, such as In, Ga, As, Sb, other III-V or IV elements, may be blocked by the polarizer stencil mask. FIG. 14A schematically shows the selective growth (1401) of Selective Area Growth (SAG) of a semiconductor by allowing only the deposition of precursors (1402) to reach the substrate at a predefined pattern geometry. In this example, the elevation angle of the evaporation source is θ=90°, meaning that the evaporation of material is performed perpendicular to the substrate. A second evaporation step of a material (1403) may be performed on top of the generated SAG using a different pattern, shown in FIG. 14B.

FIG. 14 shows the fabrication of superconducting circuit devices and extends the use of the polarizer stencil mask to super-semi-conducting hybrid devices. The figure introduces a method based on performing three sequential evaporation steps to create a super-semi-super structure. Said structure may be connected to either a standard transmon circuitry or used for DC transport measurements by attaching it to contact pads as a starting point. It may be considered device configurations that include a long semiconducting channel covered by superconductor, except for a small segment to create a weak link. With this configuration, only two evaporation steps are needed to pattern the device. To incorporate a side gate, it can either be added during a second evaporation step or by utilizing an additional third evaporation at a different angle, similar to the previous protocol.

The polarizer stencil mask may be used to selectively imprint a pattern wherein a semiconductor is grown on the substrate. The semiconductor growth may be performed by any ultra-high vacuum, high vacuum, vacuum or atmospheric pressure semiconductor growth mechanisms, such as for example Molecular Beam Epitaxy, Metal Organic Chemical Vapour Deposition or Sputtering. Preferably, the polarizer stencil mask may be used in any evaporation system or system that allows to grow layer by layer materials.

Similarly, the polarizer stencil mask may be used to selectively remove material from the substrate in a predefined pattern by any etching technique, particle bombardment or temperature annealing.

The substrate underneath the polarizer stencil mask may be substantially flat, preferably a crystalline single side polished substrate. It may as well be flexible or non-rigid compatible with flexible electronics. Generally speaking, the substrate may be comprised by any surface that allows the deposition of material onto it.

The polarizer stencil mask may be placed substantially parallel on top of the substrate. Fabrication uncertainties of ±10° may be expected in the placement of the stencil mask on top of the substrate.

A person skilled in the art would understand that making modifications in the sizes or arrangements of the different elements comprising the polarizer stencil mask may be considered without departing from the idea and scope of the present disclosure. In general, any evaporation process might be used together with the herein disclosed polarizer stencil mask. Any trivial modification on the substrate shape or composition or on the dimensions of the mask are also understood as trivial.

### Items

1. A stencil mask for defining at least one pattern on a substrate during evaporation of material from an evaporation source, the stencil mask comprising,
   a. a membrane having a top surface and bottom surface and a thickness therebetween of at least 200 nm defining the thickness of the membrane, and
   b. at least one set of parallel slits extending through the thickness of the membrane,
wherein the slits are defined such that the material coming from the evaporation source is blocked by the stencil mask or deposited onto the substrate depending on the alignment of said source with the stencil mask.
2. The stencil mask according to item 1, wherein each set of parallel slits is configured to define a distinct pattern on the substrate during evaporation.
3. The stencil mask according to any of the preceding items, wherein the thickness of membrane is at least 200 nm, preferably at least 1 μm, more preferably at least 3, most preferably at least 5 μm.
4. The stencil mask according to any of the preceding items, wherein the width of parallel slits is >10 nm, preferably 200 nm.
5. The stencil mask according to any of the preceding items, wherein the separation between parallel slits is >10 nm, preferably 50 nm.
6. The stencil mask according to any of the preceding items, wherein the length of the sets of slits is >50 nm, preferably 1 μm, more preferably 10 μm, even more preferably 100 μm.
7. The stencil mask according to any of the preceding items, wherein each set of parallel slits is defined at different surface in-plane angles of the membrane.
8. The stencil mask according to any of the preceding items, wherein the difference in azimuth angle between each set of parallel slits is ≥1°.
9. The stencil mask according to any of the preceding items, wherein the side walls of the sets of parallel slits are fabricated perpendicular to the plane of the surface of the membrane.
10. The stencil mask according to any of the preceding items, wherein the side walls of the sets of parallel slits are fabricated at an angle <90° with respect to the plane of the surface of the membrane.
11. The stencil mask according to any of the preceding items, wherein the stencil mask is comprised of a selectively etching material, preferably selected from the group of semiconductors such as Si, SiN, SiC or ceramics.
12. The stencil mask according to any of the preceding items, wherein the mask is comprised of a material resistant to chemical agents capable of dissolving metals, preferably selected from the group of semiconductors such as Si, SiN, SiC or ceramics.
13. The stencil mask according to any of the preceding items, wherein the mask is comprised of a material mechanically and chemically stable at temperatures of hundreds of ° C., preferably 500° C., preferably selected from the group of semiconductors such as Si, SiN, SiC, ceramics or etchable metals.
14. The stencil mask according to any of the preceding items, wherein two sets of parallel slits are defined in interleaving superposition defining a mesh of slits.
15. The stencil mask according to any of the preceding items, wherein the two sets of parallel slits defining the mesh are defined forming an angle between each other, preferably orthogonal.
16. The stencil mask according to any of the preceding items, wherein the side walls of each of the parallel slits comprising a set define a different angle with respect to the plane of the surface of the membrane.
17. The stencil mask according to item 1, wherein the angle between each side walls of the parallel slits with respect to the plane of the surface of the membrane is monotonically increasing.
18. The stencil mask according to any of the preceding items, wherein the slits comprising a set have a polyhedral closed shape, such as a square, a rectangle or a circle.
19. A method for defining a plurality of patterns on a substrate by evaporation from one or more evaporation sources using different evaporation materials, the method comprising the steps of
   a) providing a substrate and a stencil mask comprising a plurality of sets of parallel slits,
   b) rotating the substrate to a predefined azimuth and elevation angles defined between a plane of the surface of the mask and the spatial location of the evaporating source with respect to the mask,
   c) evaporating one or more materials over the mask, and
   d) optionally repeating steps b) and c) until all the intended materials are deposited.
20. The method according to item 19, wherein more than one evaporated material is deposited at the same azimuth and elevation angle, defining the same pattern on the substrate.
21. The method according to items 19-20, wherein at least one evaporated material is deposited at the different azimuth and elevation angle, defining different patterns on the substrate.
22. The method according to items 19-21, wherein the evaporation of materials in different or identical patterns is performed simultaneously.
23. The method according to items 19-22, wherein the evaporation of materials in different or identical patterns is performed in a specific temporal order.
24. The method according to items 19-23, wherein the substrate is comprised of a solid flat surface material, such as crystalline semiconductor GaAs, GaSb, InP, InAs, InSb, Si, SiC, SiN, semiconductor alloys, sapphire or other materials compatible with semiconductor growth processes.
25. The method according to items 19-24, wherein the evaporations are comprised of materials compatible with ultra high vacuum evaporation process, such as metals like Al, Au, Ag, Pb, or semiconductor growth precursors.
26. The method according to items 19-25, wherein the area covered by the pattern generated by the evaporated materials has a surface area of >0.01 μm², preferably >1 μm², more preferably >10 μm², even more preferably >100 μm².
27. The method according to any of items 19-26, wherein the stencil mask is the stencil mask according to any of items 1-18.

1-21. (canceled)

22. A stencil mask for defining a plurality of patterns on a substrate during evaporation of material from an evaporation source, the stencil mask comprising,
a) a membrane having a top surface and bottom surface and a thickness therebetween of at least 200 nm defining the thickness of the membrane, and
b) at least one set of parallel slits extending through the thickness of the membrane, wherein the width of parallel slits is at least 10 nm.

23. The stencil mask of claim 22, wherein each set of parallel slits is configured to define a distinct pattern on the substrate during evaporation.

24. The stencil mask of claim 22, wherein the thickness of the membrane is at least 1 μm.

25. The stencil mask of claim 22, wherein the width of parallel slits is at least 200 nm.

26. The stencil mask of claim 22, wherein the separation between parallel slits is at least 10 nm.

27. The stencil mask of claim 22, wherein the length of the sets of slits is at least 50 nm.

28. The stencil mask of claim 27, wherein the length of the sets of slits is at least 1 μm.

29. The stencil mask of claim 22, wherein least two sets of parallel slits is defined at different surface in-plane angles of the membrane.

30. The stencil mask of claim 22, wherein the side walls of the sets of parallel slits are fabricated perpendicular to the plane of the surface of the membrane.

31. The stencil mask of claim 22, wherein the side walls of the sets of parallel slits are fabricated at an angle <90° with respect to the plane of the surface of the membrane.

32. The stencil mask of claim 22, wherein the stencil mask is comprised of a selectively etching material.

33. The stencil mask of claim 22, wherein the mask is comprised of a material mechanically and chemically stable at temperatures in excess of 100° C.

34. The stencil mask of claim 33, wherein the mask is comprised of a material mechanically and chemically stable at 500° C.

35. The stencil mask of claim 22, wherein two sets of parallel slits are defined in interleaving superposition defining a mesh of slits.

36. The stencil mask of claim 22 wherein the stencil mask material is selected from the group of semiconductors or ceramics.

37. The stencil mask of claim 22, wherein the mask is comprised of a material selected from the group of semiconductors, ceramics and etchable metals.

38. A method for defining a plurality of patterns on a substrate by evaporation from one or more evaporation sources using different evaporation materials, the method comprising the steps of
c) providing a substrate,
d) providing at least one evaporation source located above the substrate,
e) providing a stencil mask substantially parallel to the substrate, located between the substrate and the at least one evaporation source, said mask comprising a plurality of sets of parallel slits,
f) rotating the stencil mask to an in-plane azimuth angle around an axis perpendicular to the surface substrate of the stencil mask,
g) rotating the stencil mask to an elevation angle defined as the smallest angle between the substrate and the at least one evaporation source, and
h) evaporating one or more materials over the mask.

39. The method of claim 38, wherein at least one evaporated material is deposited at the different azimuth and elevation angle, defining different patterns on the substrate.

40. The method of claim 38, wherein the slits are defined such that the material coming from the evaporation source is blocked by the stencil mask or deposited onto the substrate depending on the alignment of said source with the stencil mask.

41. The method of claim 38, wherein the evaporation of materials in different or identical patterns is performed simultaneously, or in a specific temporal order.

42. The method of claim 38, wherein the substrate is comprised of a solid flat surface material.

43. The method of claim 38, wherein the evaporations are comprised of materials compatible with ultra high vacuum evaporation process.

44. The method of claim 38, wherein the area covered by the pattern generated by the evaporated materials has a surface area of >0.01 μm².

45. The method of claim 44, wherein the area covered by the pattern generated by the evaporated materials has a surface area of >1 μm².

46. The method of claim 45, wherein the area covered by the pattern generated by the evaporated materials has a surface area of >10 μm².

47. The method of claim 38, wherein the stencil mask is the stencil mask of claim 22.

48. The method of claim 38, further comprising repeating steps d) to f) until all the intended materials are deposited.

49. The method of claim 38, wherein the substrate is comprised of a solid flat surface material selected from the group of crystalline semiconductor GaAs, GaSb, InP, InAs, InSb, Si, SiC, SiN, semiconductor alloys, sapphire and other materials compatible with semiconductor growth processes.

50. The method of claim 38, wherein the evaporations are comprised of materials compatible with ultra high vacuum evaporation process, selected from the group of metals Al, Au, Ag, Pb and semiconductor growth precursors.
